(19) United States
(12) Patent Application Publication
(10) Pub. No.: US 2025/0252990 A1
(43) Pub. Date: Aug. 7, 2025

(54) ADVANCED CLOCK SIGNAL DRIVERS AND MEMORY SYSTEMS INCLUDING THE SAME

(71) Applicant: Samsung Electronics Co., Ltd., Suwon-si (KR)

(72) Inventor: Bumsoo Lee, Suwon-si, (KR)

(21) Appl. No.: 18/925,340

(22) Filed: Oct. 24, 2024

(30) Foreign Application Priority Data
Feb. 1, 2024 (KR) 10-2024-0015822

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A clock signal driver includes a driver circuit configured generate an output clock signal in response to a combination of an input clock signal, a delay control signal and a power supply voltage. The driver circuit includes a main driver circuit, which is configured to generate the output clock signal in response to the input clock signal, and a replica circuit having a structure equivalent to the main driver circuit; the replica circuit is configured to generate a replica clock signal, which is equivalent to the output clock signal, in response to the input clock signal. A delay control circuit is also provided and is responsive to the replica clock signal. The delay control circuit is configured to generate the delay control signal to correct a delay change in the output clock signal, which is caused by a change in voltage level of the power supply voltage.

### REFERENCE TO PRIORITY APPLICATION

This application claims priority under 35 USC § 119 to Korean Patent Application No. 10-2024-0015822, filed Feb. 1, 2024, the disclosure of which is hereby incorporated herein by reference.

### BACKGROUND

### 1. Technical Field

Example embodiments relate generally to integrated circuit memory devices and, more particularly, to clock signal drivers and memory systems including the same.

### 2. Description of the Related Art

Memory devices, such as synchronous dynamic random access memory (DRAM) devices, typically operate in synchronization with an external clock signal. As an operating speed of the memory devices increases, the memory devices may include clock signal drivers for controlling a timing of the clock signal to gain a timing budget.

Recently, as a size of metal oxide semiconductor (MOS) transistors included in the clock signal drivers has decreased, a delay of the clock signal has become more sensitive to changes in power supply voltages and temperature. Accordingly, research is being conducted to more accurately control the timing of clock signals so that they are less susceptible to changes in power supply voltage and temperature.

### SUMMARY

At least one example embodiment of the present disclosure provides a clock signal driver that is capable of generating an output clock signal with a substantially constant output timing that is less susceptible to fluctuations in a power supply voltage, and a memory system including the clock signal driver.

According to an embodiment, a clock signal driver includes a driver circuit configured generate an output clock signal in response to a combination of an input clock signal, a delay control signal and a power supply voltage. The driver circuit includes a main driver circuit, which is configured to generate the output clock signal in response to the input clock signal, and a replica circuit having a structure equivalent to the main driver circuit; the replica circuit is configured to generate a replica clock signal, which is equivalent to the output clock signal, in response to the input clock signal. A delay control circuit is also provided and is responsive to the replica clock signal. The delay control circuit is configured to generate the delay control signal to correct a delay change in the output clock signal, which is caused by a change in voltage level of the power supply voltage.

According to another embodiment, a memory system is provided that includes a clock signal driver, a plurality of memory devices, and a host device. The clock signal driver is configured to generate an output clock signal based on an input clock signal. The plurality of memory devices are configured to receive the output clock signal from the clock signal driver, and to operate based on the output clock signal. The host device is configured to supply the input clock signal to the clock signal driver, and to control the clock signal driver and the plurality of memory devices. Advantageously, the clock signal driver includes a driver circuit and a delay control circuit. The driver circuit is configured to operate based on a power supply voltage, and to generate the output clock signal based on the input clock signal and a delay control signal. The driver circuit includes a main driver circuit and a matched replica circuit. The main driver circuit is configured to generate the output clock signal, whereas the replica circuit, which has a same structure as the main driver circuit, is configured to generate a replica clock signal identical to the output clock signal. The delay control circuit is configured to generate the delay control signal for correcting a delay change in the output clock signal based on the replica clock signal. The delay change in the output clock signal occurs depending on a change in a voltage level of the power supply voltage.

According to a further embodiment, a clock signal driver includes a driver circuit and a delay control circuit. The driver circuit is configured to operate based on a power supply voltage, and to generate an output clock signal based on an input clock signal and a delay control signal. The driver circuit includes a control circuit, a main driver operating circuit, a main driver circuit, and a replica circuit. The control circuit is configured to receive the input clock signal, and to generate a first clock signal by adjusting a phase or a delay of the input clock signal. The main driver operating circuit is configured to generate a second clock signal based on the first clock signal and the delay control signal. The main driver circuit is configured to generate the output clock signal based on the second clock signal. The replica circuit has a same structure as the main driver circuit, and is configured to generate a replica clock signal identical to the output clock signal. The delay control circuit is configured to operate based on a first voltage that is different from the power supply voltage and has a constant voltage level. The delay control circuit includes a flip-flop and a logic calculating circuit. The flip-flop is configured to output a result signal based on the replica clock signal and a unit pulse signal. The logic calculating circuit is configured to generate the unit pulse signal, and to generate the delay control signal for correcting a delay change in the output clock signal based on the result signal. The delay change in the output clock signal occurs depending on a change in a voltage level of the power supply voltage.

Advantageously, in the clock signal drivers according to example embodiments, a delay depending on the change in the voltage level of the power supply voltage of the output clock signal may be controlled by the delay control circuit, which is not affected by the power supply voltage. Thus, during a wafer test process, the delay control circuit may measure a delay change in the replica clock signal occurring depending on the change in the voltage level of the power supply voltage, and may reflect the delay change in the driver circuit (or compensate for the delay change). While the clock signal driver operates after the wafer test process, the driver circuit may output the output clock signal such that the delay of the output clock signal generated for each voltage level of the power supply voltage is constant. Accordingly, the output clock signal may have constant output timing regardless of the voltage level of the power supply voltage, and an operational stability of the clock signal driver may be improved.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a clock signal driver according to example embodiments.

FIGS. 2 and 3 are timing diagrams for describing a clock signal driver according to example embodiments.

FIG. 4 is a detailed electrical schematic illustrating an example of a main driver circuit and a replica circuit included in a clock signal driver according to example embodiments.

FIG. 5 is an electrical schematic of a delay control circuit included in a clock signal driver according to example embodiments.

FIGS. 6, 7, 8, and 9 are timing diagrams for describing an operation of a delay control circuit included in a clock signal driver according to example embodiments.

FIG. 10 is a block diagram illustrating an example of a clock signal driver according to example embodiments.

FIG. 11 is a detailed electrical schematic illustrating an example of a main driver operating circuit included in a clock signal driver according to example embodiments.

FIGS. 12 and 13 are diagrams for describing a main driver operating circuit included in a clock signal driver according to example embodiments.

FIGS. 14 and 15 are block diagrams illustrating examples of a clock signal driver according to example embodiments.

FIGS. 16 and 17 are block diagrams illustrating examples of a control circuit included in a clock signal driver according to example embodiments.

FIG. 18 is a block diagram illustrating a memory system according to example embodiments.

FIGS. 19 and 20 are diagrams for describing a clock signal driver according to example embodiments.

FIG. 21 is a diagram illustrating a dual in-line memory module (DIMM) implementation of a clock signal driver according to example embodiments.

FIG. 22 is a block diagram illustrating an example of a data chip included in a memory module included in a memory system according to example embodiments.

FIG. 23 is an example of an electrical die sorting (EDS) process that can be performed while a nonvolatile memory device is being manufactured.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

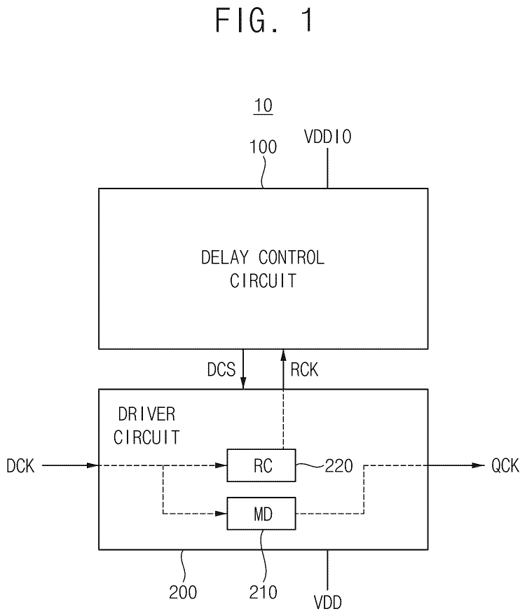

FIG. 1 is a block diagram illustrating a clock signal driver according to example embodiments. Referring to FIG. 1, a clock signal driver 10 includes a delay control circuit 100 and a driver circuit 200. The driver circuit 200 includes a main driver circuit (MD) 210 and a replica circuit (RC) 220.

The driver circuit 200 operates based on a power supply voltage VDD. For example, the driver circuit 200 may generate an output clock signal QCK having at least one characteristic based on a magnitude of the power supply voltage VDD. For example, a delay or a phase of the output clock signal QCK may change depending on a change in a voltage level of the power supply voltage VDD. For example, the delay or the phase of the output clock signal QCK may represent a time difference between a time point when an input clock signal DCK is applied and a time point when the output clock signal QCK is output.

For example, the delay control circuit 100 may operate based on a first voltage VDDIO that is different from the power supply voltage VDD and has a constant voltage level that is substantially free from fluctuation. For example, when operating at the constant voltage level, the delay control circuit 100 may independently measure and correct the delay of the output clock signal QCK without being affected by changes in the power supply voltage VDD.

For example, the change in the voltage level of the power supply voltage VDD may occur due to an automatic test equipment (ATE) to test the clock signal driver 10 during a wafer test process for the clock signal driver 10. For example, the voltage level of the power supply voltage VDD may be changed to a plurality of operating voltage levels of a plurality of memory devices connected to the clock signal driver 10.

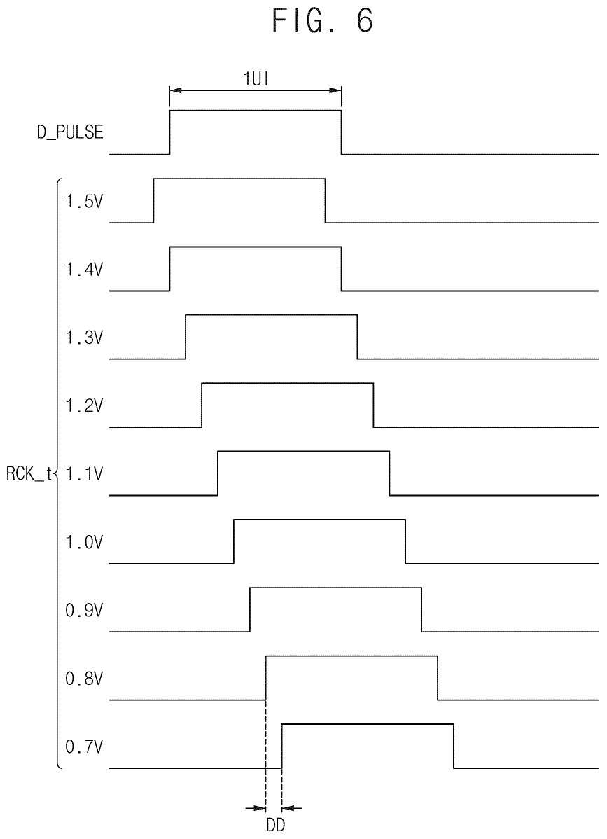

The driver circuit 200 generates the output clock signal QCK based on the input clock signal DCK and a delay control signal DCS. An operation of generating the output clock signal QCK will be described with reference to FIGS. 6 to 9.

The main driver circuit 210 generates the output clock signal QCK. For example, the main driver circuit 210 may perform an amplification operation to generate the output clock signal QCK that is provided to the plurality of memory devices connected to the clock signal driver 10. For example, the main driver circuit 210 may be referred to as an output driver or a transmitter.

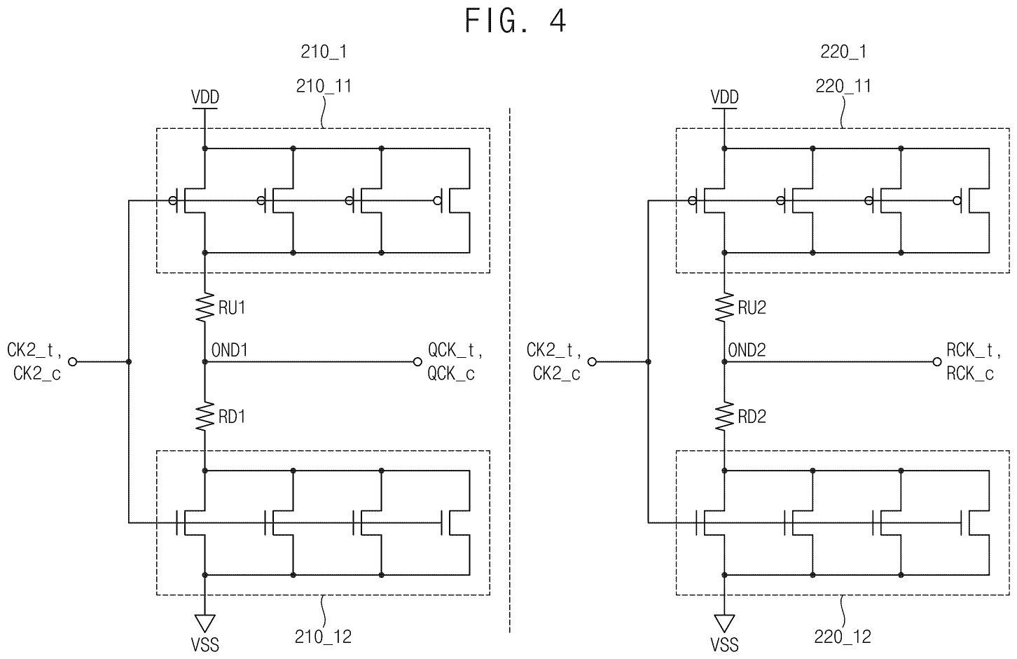

The replica circuit 220 has the same structure as the main driver circuit 210 and generates a replica clock signal RCK that is essentially identical to the output clock signal QCK. For example, when the replica circuit 220 has the same structure as the main driver circuit 210, the replica circuit 220 may generate the replica clock signal RCK to have the same phase and frequency as the output clock signal QCK. For example, a delay between the input clock signal DCK and the output clock signal QCK and a delay between the input clock signal DCK and the replica clock signal RCK may be the same. Configurations of the main driver circuit 210 and the replica circuit 220 will be described with reference to FIG. 4, as explained more fully hereinbelow.

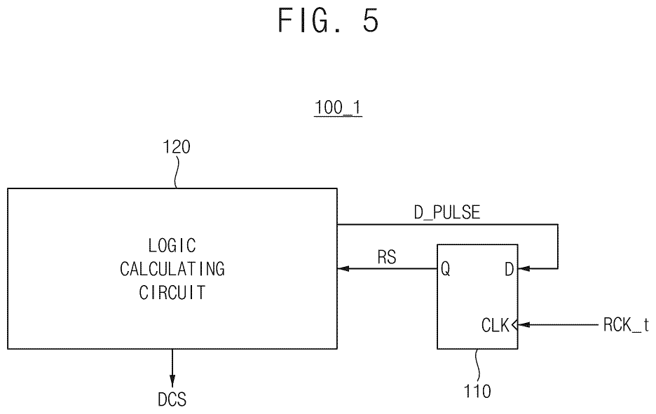

The delay control circuit 100 generates the delay control signal DCS for correcting a delay change in the output clock signal QCK based on the replica clock signal RCK, and the delay change in the output clock signal QCK occurs depending on the change in the voltage level of the power supply voltage VDD. A configuration of the delay control circuit 100 will be described with reference to FIG. 5.

For convenience of illustration only, FIG. 1 illustrates that the input clock signal DCK, output clock signal QCK, and replica clock signal RCK are single ended signals; however, example embodiments are not limited thereto. Hereinafter, example embodiments will be described based on an example where the input clock signal DCK, the output clock signal QCK, and the replica clock signal RCK are differential signals.

In the clock signal driver 10 according to example embodiments, the delay control circuit 100 may operate based on the first voltage VDDIO without being affected by the power supply voltage VDD, and thus the delay control circuit 100 may control the delay change in the output clock signal QCK occurring depending on the change in the voltage level of the power supply voltage VDD. During the wafer test process, the delay control circuit 100 may measure a delay change in the replica clock signal RCK occurring depending on the change in the voltage level of the power supply voltage VDD, and may reflect the delay change in the driver circuit 200 (or compensate for the delay change). While the clock signal driver 10 operates after the wafer test process, the driver circuit 200 may output the output clock signal QCK such that the delay of the output clock signal QCK generated for each voltage level of the power supply voltage VDD is constant. Accordingly, the output clock signal QCK may have constant output timing regardless of the voltage level of the power supply voltage VDD, and an operational stability of the clock signal driver 10 may be improved.

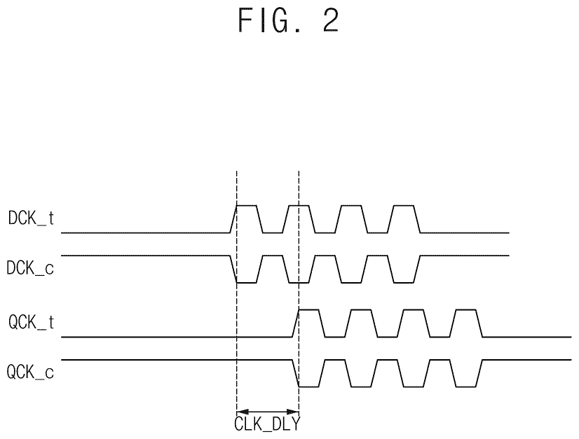

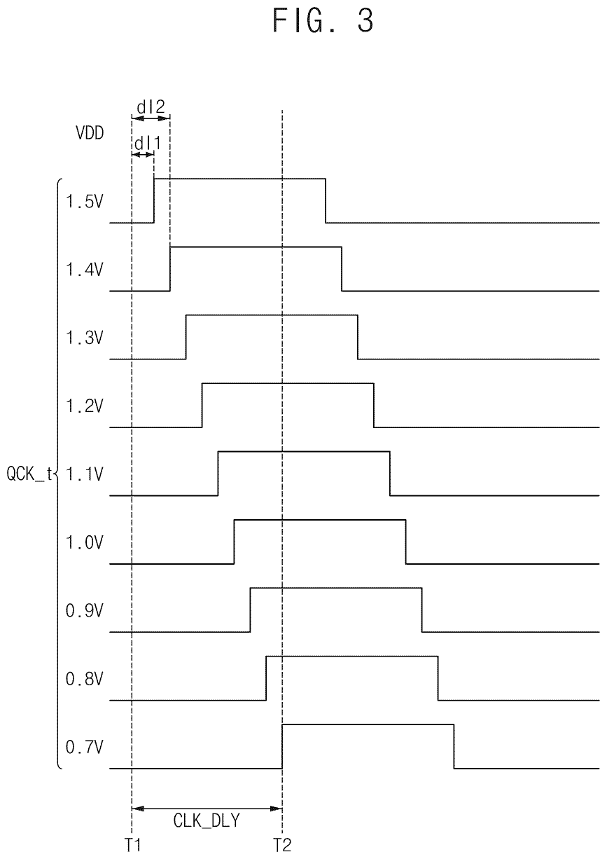

FIGS. 2 and 3 are diagrams for describing a clock signal driver according to example embodiments. Referring to FIG. 2, a first time interval CLK_DLY may represent a time difference from when input clock signals DCK_t and DCK_c are applied to the clock signal driver to when output clock signals QCK_t and QCK_c are output from the clock signal driver. For example, a time point when the output clock signals QCK_t and QCK_c are output from the clock signal driver may be substantially the same as a time point when the output clock signals QCK_t and QCK_c transition to a logic high level or a logic low level.

For example, a host device may apply the input clock signals DCK_t and DCK_c to the clock signal driver, and may request to output the output clock signals QCK_t and QCK_c after the first time interval CLK_DLY (e.g., a predetermined delay) regardless of the change in the voltage level of the power supply voltage. The clock signal driver according to example embodiments may perform the operation of delay control in which the output clock signals QCK_t and QCK_c are output after the first time interval CLK_DLY is elapsed from a time point when the input clock signals DCK_t and DCK_c are applied to the clock signal driver, regardless of the change in the voltage level change the power supply voltage.

Referring to FIG. 3, examples of the output clock signal QCK_t corresponding to different voltage levels of the power supply voltage VDD are illustrated. For example, a plurality of voltage levels of the power supply voltage VDD may be or may include a first voltage level (e.g., about 0.7V), a second voltage level (e.g., about 0.8V), a third voltage level (e.g., about 0.9V), a fourth voltage level (e.g., about 1.0V), a fifth voltage level (e.g., about 1.1V), a sixth voltage level (e.g., about 1.2V), a seventh voltage level (e.g., about 1.3V), an eighth voltage level (e.g., about 1.4V), and a ninth voltage level (e.g., about 1.5V).

For example, the operation of delay control may be performed such that the output clock signal QCK_t is output after the first time interval CLK_DLY is elapsed from a first time point T1 that indicates a time point when the input clock signal is input (or applied) to the clock signal driver.

Hereinafter, example embodiments will be described based on that a second time point T2 is a time point after the first time interval CLK_DLY is elapsed from the first time point T1. For example, the second time point T2 may represent a time point when the output clock signal QCK_t is output when the power supply voltage VDD has the first voltage level (about 0.7V). For example, as will be described with reference to FIGS. 6 to 9, the clock signal driver may set the delay control signal such that the output clock signal QCK_t is output at the second time point T2 when the power supply voltage VDD has the second to ninth voltage levels (about 0.8V, . . . , 1.5V). As a result, the output clock signal QCK_t with constant output timing may be generated by delaying the output clock signal QCK_t based on the delay control signal, regardless of the change in the voltage level of the power supply voltage VDD.

For example, the delay (or time interval) from the first time point T1 to the time point when the output clock signal QCK_t is output may be longer (or larger) as the voltage level of the power supply voltage VDD is lower. For example, a delay dl2 of the output clock signal QCK_t when the power supply voltage VDD has the eighth voltage level (about 1.4V) may be longer than a delay dl1 of the output clock signal QCK_t when the power supply voltage VDD has the ninth voltage level (about 1.5V). Therefore, as will be described with reference to FIGS. 6 to 9, the clock signal driver according to example embodiments may set the delay control signal such that the amount of delay added for correcting the output clock signal QCK_t. is larger as the voltage level of the power supply voltage VDD is higher.

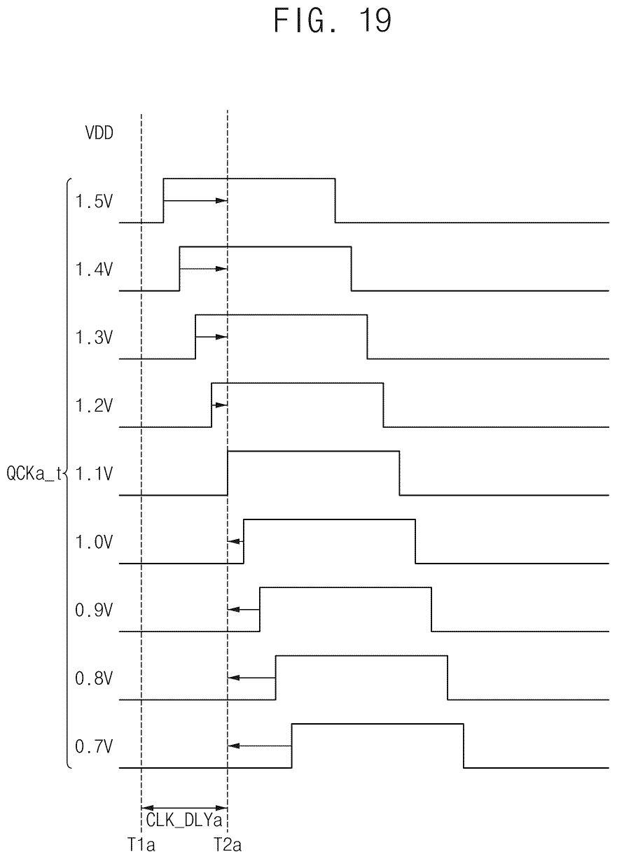

However, example embodiments are not limited thereto. For example, as will be described with reference to FIG. 19, the delay control signal may be set such that a time point when the power supply voltage VDD has the fifth voltage level (about 1.1 V) is selected as a reference time point, the phase of the output clock signal QCK_t when the power supply voltage VDD has the sixth to ninth voltage levels (about 1.2V, . . . , 1.5V) is delayed, and the phase of the output clock signal QCK_t when the power supply voltage VDD has the first to fourth voltage levels (about 0.7V, . . . , 1.0V) is pulled forward.

FIG. 4 is a circuit diagram illustrating an example of a main driver circuit and a replica circuit included in a clock signal driver according to example embodiments. Referring to FIG. 4, a main driver circuit 210_1 and a replica circuit 220_1 may represent an example embodiment of the main driver circuit 210 and the replica circuit 220 in FIG. 1.

As shown, the main driver circuit 210_1 may include a pull-up driving circuit 210_11, a pull-down driving circuit 210_12, a pull-up resistor RU1, and a pull-down resistor RD1. The pull-up driving circuit 210_11 may include a plurality of p-type metal oxide semiconductor (PMOS) transistors that are connected in parallel. The pull-down driving circuit 210_12 may include a plurality of n-type metal oxide semiconductor (NMOS) transistors that are connected in parallel. The pull-up resistor RU1 may be connected between a drain of the plurality of PMOS transistors and an output node OND1. The pull-down resistor RD1 may be connected between a drain of the plurality of NMOS transistors and the output node OND1. The main driver circuit 210_1 may receive second clock signals CK2_t and CK2_c, and may generate output clock signals QCK_t and QCK_c by amplifying the second clock signals CK2_t and CK2_c by the pull-up driving circuit 210_11 and the pull-down driving circuit 210_12. For example, the second clock signals CK2_t and CK2_c may be referred to as main driver input clock signals.

For example, the replica circuit 2201 may be identical to the main driver circuit 210_1. For example, the replica circuit 2201 may include a pull-up driving circuit 220_11, a pull-down driving circuit 220_12, a pull-up resistor RU2, and a pull-down resistor RD2. The pull-up driving circuit 220_11 may include a plurality of PMOS transistors are connected in parallel. The pull-down driving circuit 220_12 may include a plurality of NMOS transistors that are connected in parallel. The pull-up resistor RU2 may be connected between a drain of the plurality of PMOS transistors and an output node OND2. The pull-down resistor RD2 may be connected between a drain of the plurality of NMOS transistors and the output node OND2. The replica circuit 220_1 may receive the second clock signals CK2_t and CK2_c, and may generate replica clock signals RCK_t, RCK_c by amplifying the second clock signals CK2_t and CK2_c through the pull-up driving circuit 220_11 and the pull-down driving circuit 220_12. Accordingly, timing information of the replica clock signals RCK_t and RCK_c and the output clock signals QCK_t and QCK_c may be the same. For example, the timing information may include a delay with the input clock signal.

FIG. 5 is a diagram illustrating an example of a delay control circuit included in a clock signal driver according to example embodiments. Referring to FIG. 5, a delay control circuit 100_1 may represent an example embodiment of the delay control circuit 100 in FIG. 1. The delay control circuit 1001 may include a flip-flop 110 and a logic calculating circuit 120. For example, the flip-flop 110 may include a D-flip flop, but example embodiments are not limited thereto. For example, the logic circulating circuit 120 may include a circuit configuration for generating the delay control signal DCS. For example, the logic circulating circuit 120 may further include a circuit configuration for performing an operation of changing a device setting value of the driver circuit 200 in FIG. 1.

As shown, the flip-flop 110 may receive the replica clock signal RCK_t. For example, not only the clock signal driver that operates using single-ended signals, but also the clock signal driver that operates using differential signals may not use a clock signal (e.g., RCK_c) complementary to the replica clock signal RCK_t in the delay control circuit 100_1. And, the logic circulating circuit 120 may generate a unit pulse signal D_PULSE. In some embodiments, the unit pulse signal D_PULSE may have an activation time interval corresponding to 1 unit interval (UI) of data that is input to and output from the memory device operating based on the output clock signal.

The flip-flop 110 may output a result signal RS based on the replica clock signal RCK_t and the unit pulse signal D_PULSE. As shown, the flip-flop 110 may include a clock terminal CLK receiving the replica clock signal RCK_t, an input terminal D receiving the unit pulse signal D_PULSE, and an output terminal Q outputting the result signal RS. In some embodiments, the logic circulating circuit 120 may generate the delay control signal DCS based on the result signal RS. The detailed operation of generating the delay control signal DCS will be described with reference to FIGS. 6 to 9.

FIGS. 6, 7, 8, and 9 are diagrams for describing an operation of a delay control circuit included in a clock signal driver according to example embodiments. Referring to FIGS. 5 to 9, an operation of generating the result signal RS based on the replica clock signal RCK_t is illustrated, and an operation of generating an output clock signal QCK_t′ that is corrected by the unit pulse signal D_PULSE generated based on the result signal RS is illustrated. For example, the power supply voltage VDD may have the plurality of voltage levels, and the plurality of voltage levels may be or may include the first voltage level (about 0.7V), the second voltage level (about 0.8V), the third voltage level (about 0.9V), the fourth voltage level (about 1.0V), the fifth voltage level (about 1.1V), the sixth voltage level (about 1.2V), the seventh voltage level (about 1.3V), the eighth voltage level (about 1.4V), and the ninth voltage level (about 1.5V).

As shown in FIG. 6, delays of the replica clock signal RCK_t from a time point when the input clock signal is applied may be different from each other depending on the voltage level of the power supply voltage VDD. For example, as described above, the replica clock signal RCK_t and the output clock signal QCK_t are substantially the same, and therefore the replica clock signal RCK_t corresponding to the plurality of voltage levels of the power supply voltage VDD may be substantially the same as the configuration of the output clock signal QCK_t described with reference to FIG. 3. For example, the unit pulse signal D_PULSE may have the activation time interval corresponding to 1 UI. For example, the activation time interval may represent a time interval in which the unit pulse signal D_PULSE has a logic high level.

For example, the activation time interval of the unit pulse signal D_PULSE may be set sufficiently long to detect the delay change depending on the change in the voltage level of the power supply voltage VDD. In particular, the activation time interval of the unit pulse signal D_PULSE may be set longer than a delay difference DD between the replica clock signal RCK_t when the power supply voltage VDD has the first voltage level (about 0.7V) and the replica clock signal RCK_t when the power supply voltage VDD has the second voltage level (about 0.8V). Although example embodiments are described based on the case where the unit pulse signal D_PULSE has the activation time interval corresponding to 1 UI, example embodiments are not limited thereto, and the activation time interval of the unit pulse signal D_PULSE may be variously set according to example embodiments.

Although example embodiments are described based on the case where a start point of the activation time interval of the unit pulse signal D_PULSE is between a positive clock edge of the replica clock signal RCK_t when the power supply voltage VDD has the eighth voltage level (about 1.4V) and a positive clock edge of the replica clock signal RCK_t when the power supply voltage VDD has the seventh voltage level (about 1.3V), example embodiments are not limited thereto, and the start point of the activation time interval of the unit pulse signal D_PULSE may be variously set according to example embodiments.

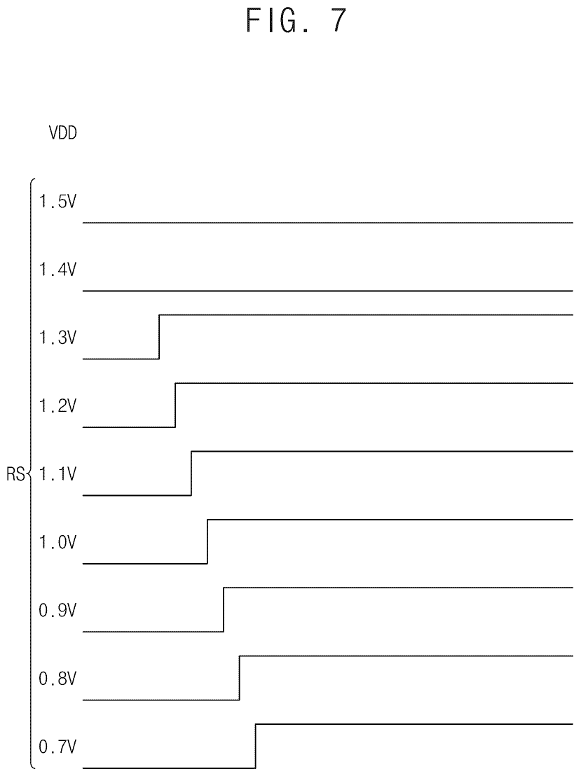

As shown in FIG. 7, the flip-flop 110 may output the result signal RS based on the unit pulse signal D_PULSE and the replica clock signal RCK_t. In addition, a logic level of the result signal RS may be synchronized with a logic level of the unit pulse signal D_PULSE at the positive clock edge of the replica clock signal RCK_t.

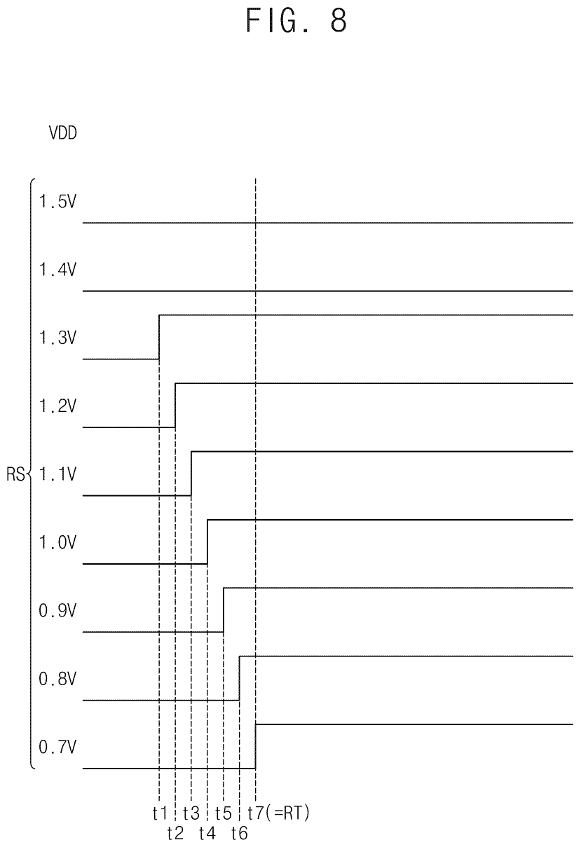

As shown in FIG. 8, the logic circulating circuit 120 may set or generate the delay control signal by analyzing the result signal RS. For example, the logic circulating circuit 120 may store a plurality of transition points t1, t2, t3, t4, t5, t6, and t7 that represent time points when the result signal RS transitions. For example, the time points when the result signal RS transitions may represent the time points when the result signal RS transitions from the logic low level to the logic high level. However, example embodiments are not limited thereto, and the result signal RS may indicate transition time points from the logic high level to the logic low level. In some example embodiments, the logic circulating circuit 120 may further include a storage unit that stores the plurality of transition points t1, t2, t3, t4, t5, t6, and t7.

According to some embodiments, the logic circulating circuit 120 may set or generate the delay control signal based on the plurality of transition time points t1, t2, t3, t4, t5, t6, and t7. Hereinafter, example embodiments will be described based on an example of setting the seventh time point t7 as a reference time point RT and unifying the delay of the output clock signal with the input clock signal. The output clock signal may correspond to the second to ninth voltage levels (about 0.8V, . . . , 1.5V) of the power supply voltage VDD.

Advantageously, the delay control signal may be set such that the driver circuit 200 in FIG. 1 delays the output clock signal with the different amount of delays depending on the voltage level of the power supply voltage VDD. For example, when the power supply voltage VDD has the second voltage level (about 0.8V), the delay control signal may be set such that the output clock signal is delayed by the time interval between the seventh time point t7 and the sixth time point t6. And, when the power supply voltage VDD has the third voltage level (about 0.9V), the delay control signal may be set such that the output clock signal is delayed by the time interval between the seventh time point t7 and the fifth time point t5. Further, when the power supply voltage VDD has the fourth, fifth, sixth, and seventh voltage levels (about 1.0V, 1.1V, 1.2V, and 1.3V), the delay control signal may be set such that the output clock signal is delayed as in the case where the power supply voltage VDD has the second and third voltage levels (about 0.8V and 0.9V).

Next, when the power supply voltage VDD has the eighth and ninth voltage levels (about 1.4V and 1.5V), the result signal RS may not transition. For example, when the power supply voltage VDD has the eighth and ninth voltage levels (about 1.4V and 1.5V), the amount of delay may be predicted or expected from the plurality of transition points t1, t2, t3, t4, t5, t6, and t7. The amount of delay may be proportional to the change in the voltage level of the power supply voltage VDD. For example, since adjacent voltage levels among the first to ninth voltage levels (about 0.7V, . . . , 1.5V) of the power supply voltage VDD have a difference of about 0.1V, time intervals of adjacent transition points among the plurality of transition points (t1, t2, t3, t4, t5, t6, and t7) may all be the same. The time interval between the first time point t1 and the second time point t2, the time interval between the second time point t2 and the third time point t3, the time interval between the third time point t3 and the fourth time point t4, the time interval between the fourth time point t4 and the fifth time point t5, the time interval between the fifth time point t5 and the sixth time point t6, and the time interval between the sixth time point t6 and the seventh time point t7 may all be the same. Therefore, when the power supply voltage VDD has the eighth and ninth voltage levels (about 1.4V and 1.5V), the amount of delay may be predicted from the time intervals of adjacent transition points among the plurality of transition points t1, t2, t3, t4, t5, t6, and t7. And, when the power supply voltage VDD has the eighth voltage level (about 1.4V), the amount of delay may be seven times the time interval between the seventh time point t7 and the sixth time point t6.

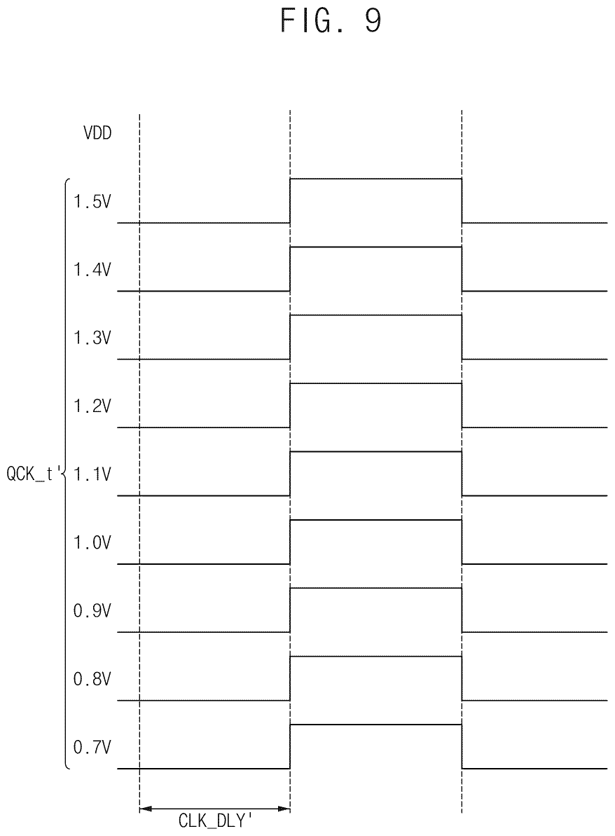

As shown in FIG. 9, the output clock signal QCK_t′ in which the delay change is corrected based on the delay control signal may have the same amount of delay when the power supply voltage VDD has the first to ninth voltage levels (about 0.7V, . . . , 1.5V). As shown, a first time interval CLK_DLY′ from a time point when the input clock signal is applied to the clock signal driver to a time point when the output clock signal QCK_t′ is output from the clock signal driver may be fixed regardless of the first to ninth voltage levels (about 0.7V, . . . , 1.5V) of the power supply voltage VDD. The first time interval CLK_DLY′ may be substantially the same as the first time interval CLK_DLY in FIG. 2.

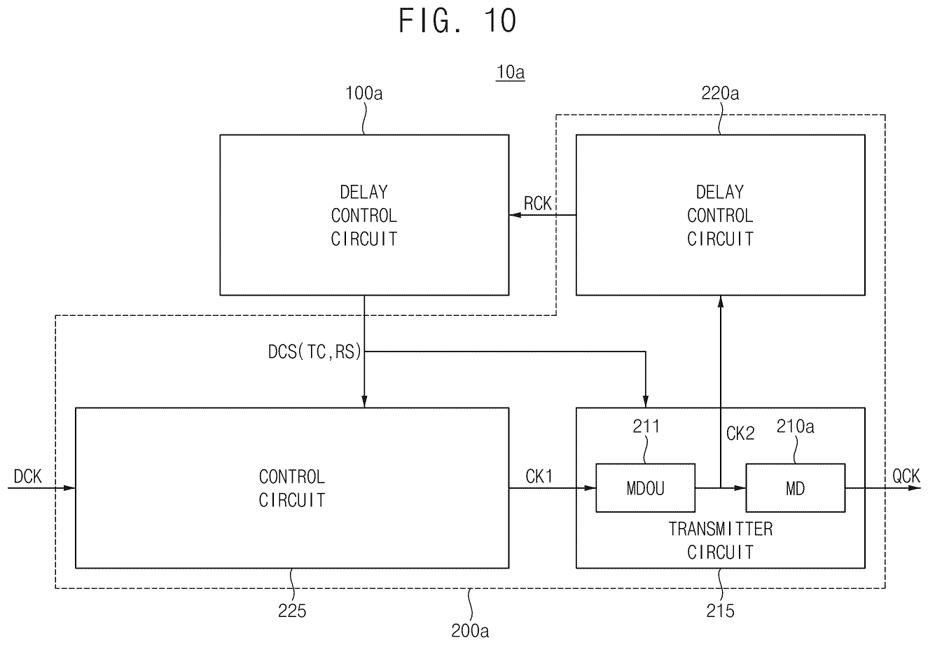

FIG. 10 is a block diagram illustrating an example of a clock signal driver according to example embodiments. Referring to FIG. 10, a clock signal driver 10a may represent an example embodiment of the clock signal driver 10 of FIG. 1. The clock signal driver 10a may include a delay control circuit 100a, and a driver circuit 200a. The driver circuit 200a may include a replica circuit 220a, a control circuit 225, and a transmitter circuit 215. The transmitter circuit 215 may include a main driver circuit 210a, and a main driver operating circuit (MDOU) 211. The delay control circuit 100a, the replica circuit 220a, and the main driver circuit 210a may be substantially the same as the delay control circuit 100, the replica circuit 220, and the main driver circuit 210 in FIG. 1, respectively. The descriptions repeated with or overlapping with descriptions of FIG. 1 will be omitted in the interest of brevity.

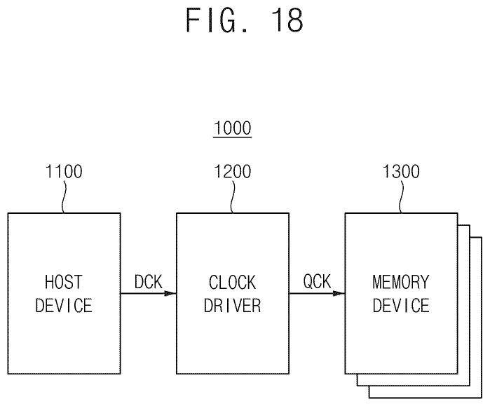

For example, the driver circuit 200a may further include the control circuit 225, which may receive the input clock signal DCK and generate a first clock signal CK1 by adjusting the phase or the delay of the input clock signal DCK. Advantageously, the control circuit 225 may correct the delay difference depending on the transmission path of the input clock signal DCK or fix the phase of the input clock signal DCK. The configuration of the control circuit 225 will be described with reference to FIGS. 18 to 20.

The driver circuit 200a may further include the main driver operating circuit 211. For example, the main driver operating circuit 211 may generate a second clock signal CK2 based on the first clock signal CK1 and the delay control signal DCS. The main driver operating circuit 211 may include a pre-driver circuit corresponding to the main driver circuit 210a. This pre-driver circuit may amplify the first clock signal CK1. For example, the pre-driver circuit may be a circuit configuration that generates a signal for driving the main driver circuit 210a.

The main driver operating circuit 211 may further include a delay cell circuit, which may correct the delay change in the output clock signal QCK that occurs depending on the change in the voltage level of the power supply voltage. In some embodiments, the delay cell circuit may perform an operation of delay adjustment to correct the delay change occurring depending on the change in the voltage level of the power supply voltage in the first clock signal CK1.

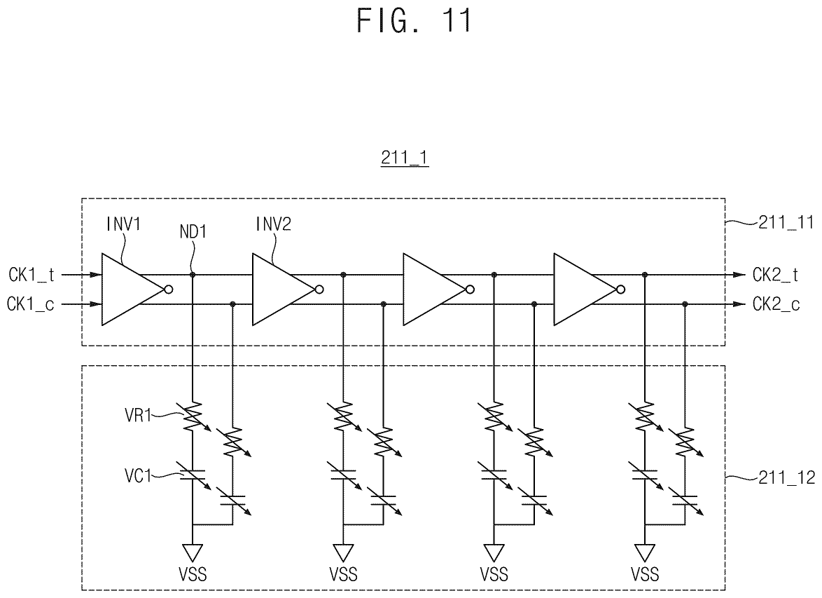

Configurations of the pre-driver circuit and the delay cell circuit will be described with reference to FIG. 11. Here, the delay control signal DCS may include a trimming code TC applied to the main driver operating circuit 211 to correct the delay change in the output clock signal QCK. For example, the trimming code TC may be applied to the delay cell circuit included in the main driver operating circuit 211. For example, the trimming code TC may be a code that determines a correction delay applied by the delay cell circuit to the first clock signal CK1. The delay control signal DCS may further include a register signal RS for changing the device setting value of the driver circuit 200a to additionally correct the delay change in the output clock signal QCK.

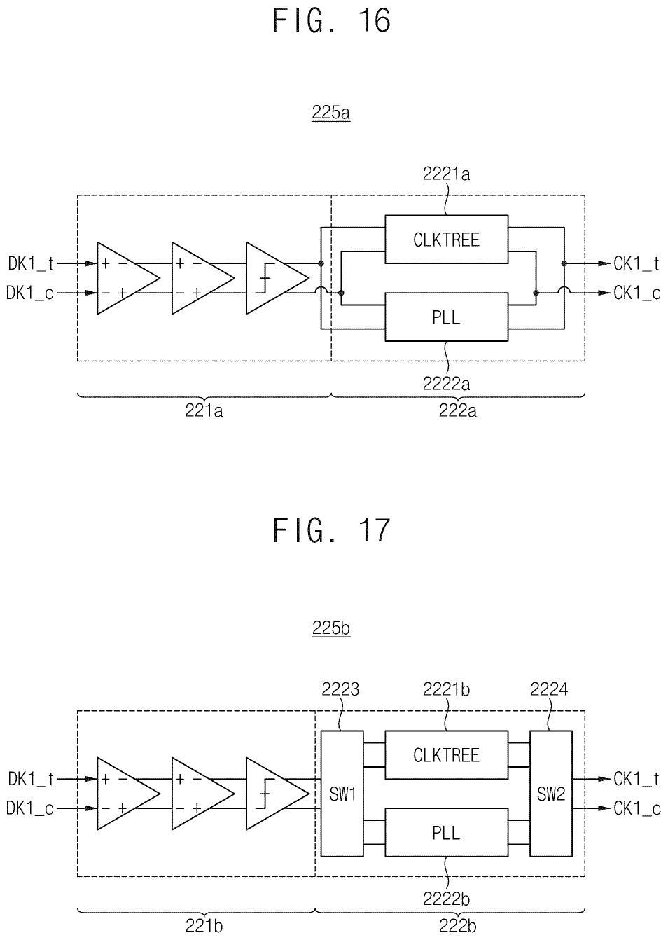

The device setting value may include a gain of the control circuit 225, an intensity of a current flowing through the control circuit 225 and a transistor strength value of the main driver circuit 210a. The transistor strength value of the main driver circuit 210a may refer to a current drivability of the transistors included in the main driver circuit 210a. And, the register signal RS may include a signal for controlling a phase locked loop (PLL) as will be described with reference to FIG. 16.

FIG. 11 is a circuit diagram illustrating an example of a main driver operating circuit included in a clock signal driver according to example embodiments. Referring to FIG. 11, a main driver operating circuit 211_1 may represent an example embodiment of the main driver operating circuit 211 in FIG. 10. The main driver operating circuit 211_1 may include a pre-driver circuit 211_11 and a delay cell circuit 211_12.

For example, the pre-driver circuit 211_11 may include a plurality of inverters connected in series (or cascade-connected). Although FIG. 11 illustrates that the pre-driver circuit 211_11 includes four inverters, example embodiments are not limited thereto, and the number of inverters may be fewer or more.

The delay cell circuit 211_12 may include a plurality of variable resistors and a plurality of variable capacitors. And, the first clock signals CK1_t and CK1_c may be delayed or pulled forward by the plurality of variable resistors and the plurality of variable capacitors such that the second clock signals CK2_t and CK2_c are generated. The trimming code (e.g., TC in FIG. 10) may be a code that determines resistances of the plurality of variable resistors and capacitances of the plurality of variable capacitors.

For example, the plurality of inverters may include a first inverter INV1 and a second inverter INV2, and an input of the first inverter INV1 and an output of the second inverter INV2 may be connected to a first node ND1. For example, the plurality of variable resistors may include a first variable resistor VR1, and a plurality of variable capacitors may include a first variable capacitor VC1. For example, the first variable resistor VR1 and the first variable capacitor VC1 may be connected in series between the first node ND1 and a ground voltage VSS.

Although example embodiments are described based on the case where the first variable resistor VR1 and the first variable capacitor VC1 are connected in series between the first node ND1 and the ground voltage VSS in the main driver operating circuit 211_1 of FIG. 11, example embodiments are not limited thereto. For example, the first variable resistor VR1 and the first variable capacitor VC1 may be connected in parallel between the first node ND1 and the ground voltage VSS, or may be directly connected to an internal circuit of the first inverter INV1 or the second inverter INV2 other than between the first node ND1 and the ground voltage VSS.

Although example embodiments are described based on an RC circuit for correcting the delay change occurring depending on the change in the voltage level of the power supply voltage in the main driver operating circuit 211_1, example embodiments are not limited thereto. For example, the delay applied to the first clock signals CK1_t and CK1_c may be controlled by adjusting an activation level of the plurality of transistors included in the plurality of inverters. For example, the trimming code (TC in FIG. 10) may be a code that determines a degree of activation of the plurality of transistors.

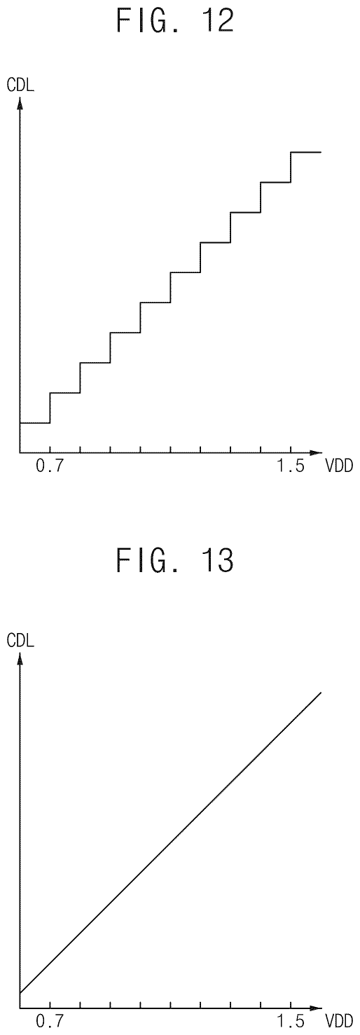

FIGS. 12 and 13 are diagrams for describing a main driver operating circuit included in a clock signal driver according to example embodiments. Referring to FIG. 12, examples of a correction delay CDL depending on the change in the voltage level of the power supply voltage VDD are illustrated. The correction delay CDL may be the delay applied to the first clock signal (e.g., CK1 in FIG. 10) to correct the delay change in the output clock signal occurring depending on the change in the voltage level of the power supply voltage VDD. For example, the trimming code (TC in FIG. 10) may include the correction delay CDL corresponding to the voltage level of the power supply voltage VDD.

In some example embodiments, the correction delay CDL may increase discretely as the voltage level of the power supply voltage VDD increases. For example, the delay applied to the first clock signal (e.g., CK1 in FIG. 10) may be the same in both cases where the voltage level of the power supply voltage VDD is about 0.72V and where the voltage level of the power supply voltage VDD is about 0.78V.

Referring to FIG. 13, examples of the correction delay CDL depending on the change in the voltage level of the power supply voltage VDD are illustrated. The descriptions repeated with or overlapping with descriptions of FIG. 12 will be omitted in the interest of brevity. The correction delay CDL may increase linearly in proportion to the voltage level of the power supply voltage VDD. For example, the delay applied to the first clock signal (e.g., CK1 in FIG. 10) may be different in cases where the voltage level of the power supply voltage VDD is about 0.72V and where the voltage level of the power supply voltage VDD is about 0.78V.

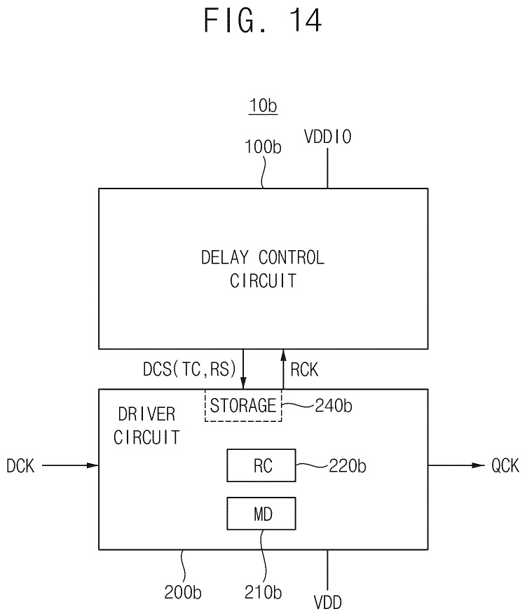

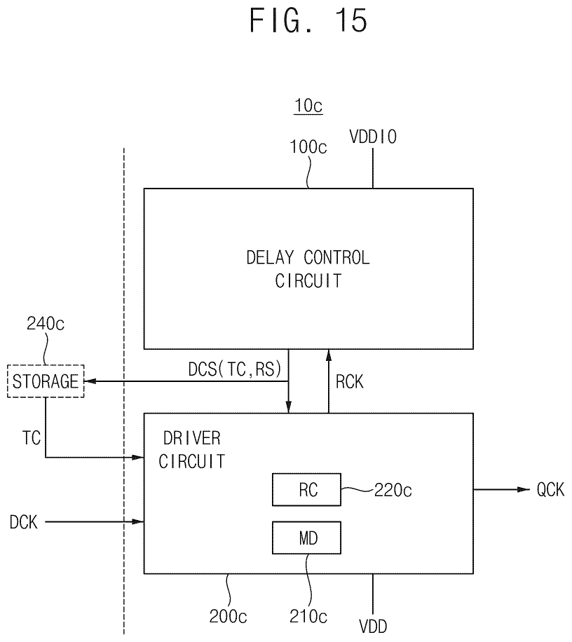

FIGS. 14 and 15 are block diagrams illustrating examples of a clock signal driver according to example embodiments. Referring to FIG. 14, a clock signal driver 10b may be an example embodiment of the clock signal driver 10 of FIG. 1. The clock signal driver 10b may further include a storage 240b, as compared with the clock signal driver 10 of FIG. 1. The descriptions repeated with or overlapping with descriptions of FIG. 1 will be omitted in the interest of brevity.

The storage 240b may be a space where the trimming code TC is stored. For example, the storage 240b may be disposed inside a driver circuit 200b. For example, the trimming code TC may be stored in the storage 240b during the wafer test process, and then may be used when operating the clock signal driver 10b. For example, when operating the clock signal driver 10b, the delay of the output clock signal QCK may be adjusted using the trimming code TC corresponding to the voltage level of the power supply voltage VDD. For example, the storage 240b may additionally store the register signal RS.

Referring to FIG. 15, a clock signal driver 10c may be substantially the same as the clock signal driver 10 of FIG. 1. The clock signal driver 10c may exchange signals with a storage 240c disposed outside the clock signal driver 10c. The descriptions repeated with or overlapping with descriptions of FIG. 1 will be omitted in the interest of brevity. The storage 240c may be a space where the trimming code TC is stored. For example, the storage 240c may be disposed outside the clock signal driver 10c. For example, the trimming code TC may be stored in the storage 240c during the wafer test process, and then may be transferred from the storage 240c to the clock signal driver 10c when operating the clock signal driver 10c. For example, the clock signal driver 10c may adjust the delay of the output clock signal QCK by referring to the trimming code TC corresponding to the voltage level of the power supply voltage VDD in the storage 240c when operating the clock signal driver 10c. For example, the register signal RS may be stored inside the driver circuit 200c, unlike the trimming code TC.

FIGS. 16 and 17 are block diagrams illustrating examples of a control circuit included in a clock signal driver according to example embodiments.

Referring to FIG. 16, a control circuit 225a may be an example embodiment of the control circuit 225 in FIG. 10. The control circuit 225a may include a receiving circuit 221a, a clock tree circuit (CLKTREE) 2221a, and a phase locked loop 2222a. The receiving circuit 221a may receive and amplify the input clock signals DCK_t and DCK_c. For example, the receiving circuit 221a may include a plurality of inverters or a plurality of buffers to amplify the input clock signals DCK_t and DCK_c.

For example, the clock tree circuit 2221a may be a circuit configuration for correcting the delay difference depending on the transmission path of the input clock signals DCK_t and DCK_c. For example, the clock tree circuit 2221a may be referred to as a clock repeater. For example, the clock tree circuit 2221a may correct the delay difference depending on the physical distance between clock terminals of a plurality of flip-flops and a clock source (e.g., host device). For example, the plurality of flip-flops may be flip-flops included in the plurality of memory devices connected to the clock signal driver. The phase lock loop 2222a may be a circuit configuration for locking the phases of the input clock signals DCK_t and DCK_c. For example, the phase locked loop 2222a may maintain the frequencies of the input clock signals DCK_t and DCK_c constant.

Referring to FIG. 17, a control circuit 225b may further include a plurality of switches 2223 and 2224, as compared with the control circuit 225a of FIG. 16. The descriptions repeated with or overlapping with descriptions of FIG. 16 will be omitted in the interest of brevity. One of a clock tree circuit 2221b and a phase locked loop 2222b may be selectively operated using the plurality of switches 2223 and 2224. For example, the first clock signals CK1_t and CK1_c may be generated based on one of the clock tree circuit 2221b and the phase locked loop 2222b.

FIG. 18 is a block diagram illustrating a memory system according to example embodiments. Referring to FIG. 18, a memory system 1000 includes a host device 1100, a clock signal driver 1200, and a plurality of memory devices 1300. The clock signal driver 1200 may be substantially the same as the clock signal driver 10 of FIG. 1. The descriptions repeated with or overlapping with descriptions of FIGS. 1 to 17 will be omitted in the interest of brevity.

The host device 1100 supplies an input clock signal DCK to the clock signal driver 1200 and controls the clock signal driver 1200 and the plurality of memory devices 1300. For example, when the host device 1100 directly supplies the input clock signal DCK to the plurality of memory devices 1300, the intensity of the input clock signal DCK transferred to the plurality of memory devices 1300 may be weak, and the timing conditions required for the plurality of memory devices 1300 may not be satisfied. Therefore, the host device 1100 may supply the input clock signal DCK to the clock signal driver 1200, and the clock signal driver 1200 may generate an output clock signal QCK by controlling the signal strength and the timing conditions of the input clock signal DCK.

The host device 1100 may request (or command) the plurality of memory devices 1300 to have constant input/output timing regardless of changes in a voltage level of a power supply voltage. Likewise, the host device 1100 may require the clock signal driver 1200 to have constant output timing regardless of changes in the voltage level of the power supply voltage. For example, the host device 1100 may apply the input clock signal DCK to the clock signal driver 1200 and request that the output clock signal QCK be output after a predetermined delay regardless of the change in the voltage level of the power supply voltage.

The plurality of memory devices 1300 receive the output clock signal QCK from the clock signal driver 1200 and operate based on the output clock signal QCK. For example, the plurality of memory devices 1300 may be a dynamic random access memory (DRAM).

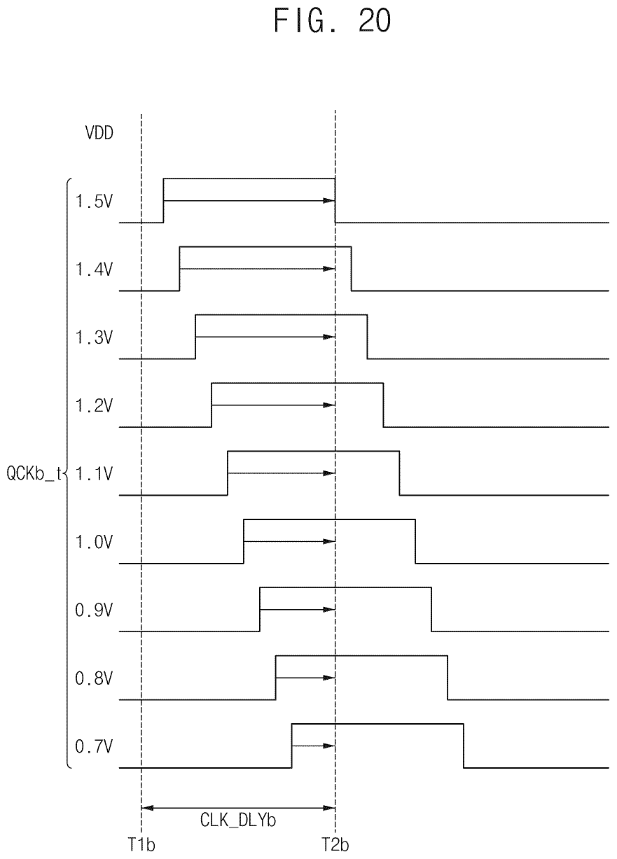

FIGS. 19 and 20 are diagrams for describing a clock signal driver according to example embodiments. Referring to FIG. 19, example embodiments are described based on the case where an output clock signal QCKa_t is requested to be output at a second time point T2a indicating a time point when a first time interval CLK_DLYa has elapsed from a first time point T1a. For example, the first time point T1a may indicate a time point when the input clock signal is input (or applied) to the clock signal driver. For example, a power supply voltage VDD may have a plurality of voltage levels, where the plurality of voltage levels include a first voltage level (e.g., about 0.7V), a second voltage level (e.g., about 0.8V), a third voltage level (e.g., about 0.9V), a fourth voltage level (e.g., about 1.0V), a fifth voltage level (about 1.1 V), a sixth voltage level (e.g., about 1.2V), a seventh voltage level (e.g., about 1.3V), an eighth voltage level (e.g., about 1.4V), and a ninth voltage level (e.g., about 1.5V). The descriptions repeated with or overlapping with descriptions of FIG. 3 will be omitted in the interest of brevity.

For example, the second time point T2a may represent a time point when the output clock signal QCKa_t is output when the power supply voltage VDD has the fifth voltage level (about 1.1 V). For example, when the power supply voltage VDD has the first voltage level (about 0.7V), the output clock signal QCKa_t may be pulled forward. For example, example embodiments will be described based on that the power supply voltage VDD has the first voltage level (about 0.7V) and an output delay from the first time point T1a to a time point when the output clock signal QCKa_t is output is 500 ps. For example, the output delay may be a delay applied by a driver circuit (200 in FIG. 1) regardless of a delay control signal. For example, the delay control signal may control the driver circuit (200 in FIG. 1) such that the output delay is shorter than about 500 ps.

Referring to FIG. 20, example embodiments are described based on the case where an output clock signal QCKb_t is requested to be output at a second time point T2b indicating a time point when a first time interval CLK_DLYb has elapsed from a first time point T1b. For example, the first time point T1b may indicate a time point when the input clock signal is input (or applied) to the clock signal driver. The descriptions repeated with or overlapping with descriptions of FIGS. 3 and 19 will be omitted in the interest of brevity.

For example, the second time point T2b may be a time point after time points when the output clock signal QCKb_t is output when the power supply voltage VDD has the first to ninth voltage levels (about 0.7V, 0.8V, . . . , 1.5V). When the power supply voltage VDD has the first voltage level (about 0.7V), the output clock signal QCKb_t may be delayed. For example, if the power supply voltage VDD has the first voltage level (about 0.7V) and an output delay from the first time point T1b to a time point when the output clock signal QCKb_t is output is 500 ps, the delay control signal may control the driver circuit (200 in FIG. 1) so that the output delay is longer than 500 ps.

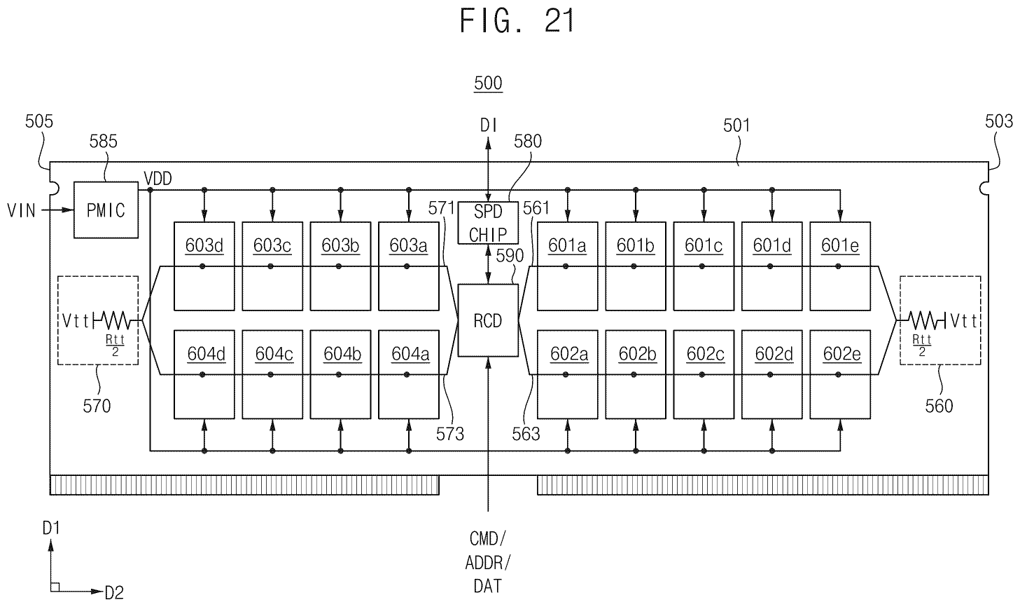

FIG. 21 is a diagram illustrating an implementation example of a clock signal driver according to example embodiments. Referring to FIG. 21, example embodiments are described based on the case where the plurality of memory devices are provided in the form of a memory module including memory packages, and the clock signal driver is provided in the form of a buffer chip. A memory module 500 may include a circuit board 501, a buffer chip 590 disposed (mounted) on a circuit board 501, and a plurality of memory devices 601a, 601b, 601c, 601d, 601e, 602a, 602b, 602c, 602d, 602e, 603a, 603b, 603c, 603d, 604a, 604b, 604c, 604d, module resistors 560, 570, a serial presence detection (SPD) chip 580, and a power management integrated circuit (PMIC) 585.

The buffer chip 590 may control the memory devices 601a to 601d, 602a to 602d, 603a to 603d, and 604a to 604d and the PMIC 585 according to the control of an external memory controller. For example, the buffer chip 590 may be a registering clock driver (RCD) and may receive an address ADDR, a command CMD, and a data DAT from the memory controller. For example, the RCD may include the clock signal driver 10 of FIG. 1. For example, the buffer chip 590 may supply the clock signal to a plurality of memory devices 601a, 601b, 601c, 601d, 601e, 602a, 602b, 602c, 602d, 602e, 603a, 603b, 603c, 603d, 604a, 604b, 604c, and 604d.

The SPD chip 580 may include electrically erasable programmable read-only memory (EEPROM). The SPD chip 580 may include initial information or device information (DI) of the memory module 500. For example, the SPD chip 580 may include initial information or device information (DI) such as module type, module configuration, storage capacity, module type, execution environment, etc. of the memory module 500. When the memory system including the memory module 500 is booted, DI is read from the SPD chip 580, and the memory module 500 is recognized/controlled/controlled based on the read DI.

The circuit board 501 may extend between a first edge portion 503 and a second edge portion 505 in a first direction D1 in a second direction D2 perpendicular to the first direction D1. For example, the circuit board 501 may be a printed circuit board (PCB). The buffer chip 590 may be disposed at the center of the circuit board 501, and the memory devices 601a to 601e and 602a to 602e may be disposed in a plurality of rows between the buffer chip 590 and the first edge portion 503. The memory devices 603a to 603d and 604a to 604d may be disposed in a plurality of rows between the buffer chip 590 and the second edge portion 505.

For example, the semiconductor memory devices 601a to 601e and 602a to 602e may be disposed in a plurality of rows between the buffer chip 590 and the first edge portion 503, and the semiconductor memory devices 603a to 603d and 604a to 604d may be disposed in a plurality of rows between the buffer chip 590 and the second edge portion 505. The semiconductor memory devices 601a to 601d, 602a to 602d, 603a to 603d, and 604a to 604d may be referred to as data chips, and the semiconductor memory devices 601e and 602e may be referred to as parity chips.

The buffer chip 590 may provide command/address signals to the memory devices 601a to 601e through the command/address transmission line 561, and provide command/address signals to the memory devices 602a to 602e through the command/address transmission line 563. Additionally, the buffer chip 590 may provide command/address signals to the semiconductor memory devices 603a to 603d through the command/address transmission line 571, and may provide command/address signals to the semiconductor memory devices 604a to 604d through the command/address transmission line 573.

The command/address transmission lines 561 and 563 may be commonly connected to the module resistance portion 560 disposed adjacent to the first edge portion 503, and the command/address transmission lines 571 and 573 may be connected to the module resistance unit 570 disposed adjacent to the second edge portion 505. The module resistance units 560 and 570 may each include a termination resistor Rtt/2 connected to a termination voltage Vtt. Each of the semiconductor memory devices 601a to 601e, 602a to 602e, 603a to 603d, and 604a to 604e may be a DRAM device.

The SPD chip 580 may be disposed adjacent to the buffer chip 590, and the PMIC 585 may be disposed between the memory device 603d and the second edge portion 505. The PMIC 585 may generate the power supply voltage VDD based on an input voltage VIN, and provide the power supply voltage VDD to the semiconductor memory devices 601a to 601e, 602a to 602e, 603a to 603d, and 604a to 604d.

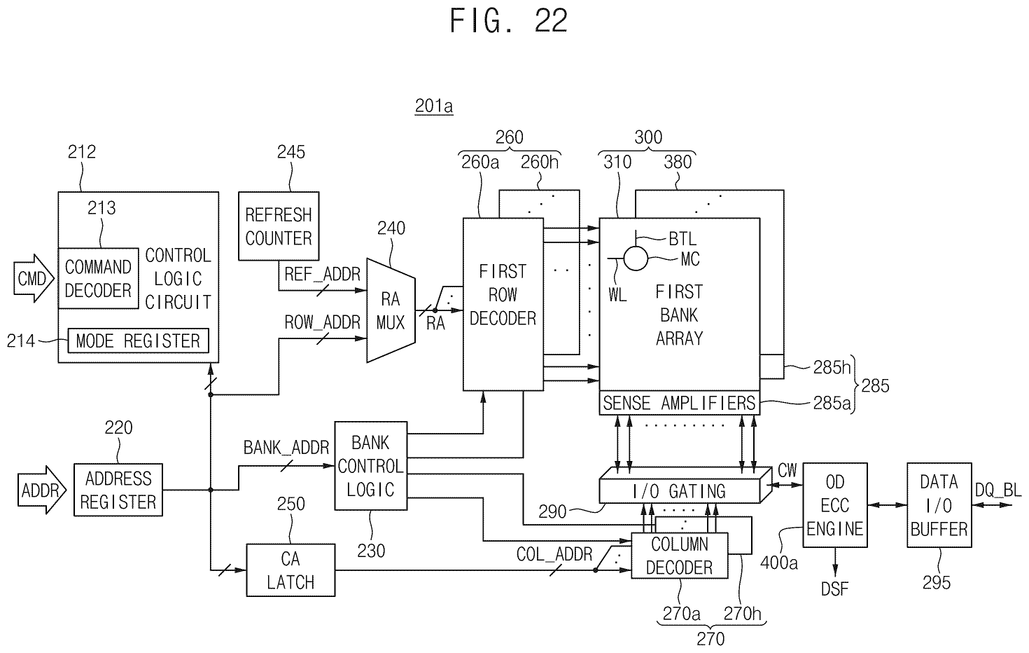

FIG. 22 is a block diagram illustrating an example of a data chip included in a memory module included in a memory system according to example embodiments. Referring to FIG. 22, a data chip 201a may include a control logic circuit 212, an address register 220, a bank control logic circuit 230, a row address multiplexer 240, a column address latch 250, a row decoder 260, a column decoder 270, a memory cell array 300, a sense amplifier unit 285, an input/output (I/O) gating circuit 290, a data I/O buffer 295, an on-die ECC engine 400a and/or a refresh counter 245. The data chip 201a may include a single number of, or a plurality of, each of the above.

The memory cell array 300 may include first to eighth bank arrays 310 to 380 (e.g., first to eighth bank arrays 310, 320, 330, 340, 350, 360, 370 and 380). The row decoder 260 may include first to eighth bank row decoders 260a to 260h connected to the first to eighth bank arrays 310 to 380, respectively. The column decoder 270 may include first to eighth bank column decoders 270a to 270h connected to the first to eighth bank arrays 310 to 380, respectively. The sense amplifier unit 285 may include first to eighth bank sense amplifiers 285a to 285h connected to the first to eighth bank arrays 310 to 380, respectively.

The first to eighth bank arrays 310 to 380, the first to eighth bank row decoders 260a to 260h, the first to eighth bank column decoders 270a to 270h, and the first to eighth bank sense amplifiers 285a to 285h may form first to eighth banks. Each of the first to eighth bank arrays 310 to 380 may include a plurality of wordlines WL, a plurality of bitlines BTL, and a plurality of memory cells MC formed at intersections of the wordlines WL and the bitlines BTL.

Although FIG. 22 illustrates the data chip 201a including eight banks, the data chip 201a may include any number of banks; for example, one, two, four, eight, sixteen, or thirty two banks, or any number therebetween one and thirty two.

The address register 220 may receive the address ADDR including a bank address BANK_ADDR, a row address ROW_ADDR and a column address COL_ADDR from the memory controller 100. The address register 220 may provide the received bank address BANK_ADDR to the bank control logic circuit 230, may provide the received row address ROW_ADDR to the row address multiplexer 240, and may provide the received column address COL_ADDR to the column address latch 250.

The bank control logic circuit 230 may generate bank control signals in response to the bank address BANK_ADDR. One of the first to eighth bank row decoders 260a to 260h corresponding to the bank address BANK_ADDR may be activated in response to the bank control signals, and one of the first to eighth bank column decoders 270a to 270h corresponding to the bank address BANK_ADDR may be activated in response to the bank control signals.

The row address multiplexer 240 may receive the row address ROW_ADDR from the address register 220, and may receive a refresh row address REF_ADDR from the refresh counter 245. The row address multiplexer 240 may selectively output the row address ROW_ADDR or the refresh row address REF_ADDR as a row address RA. The row address RA that is output from the row address multiplexer 240 may be applied to the first to eighth bank row decoders 260a to 260h.

The activated one of the first to eighth bank row decoders 260a to 260h may decode the row address RA that is output from the row address multiplexer 240, and may activate a wordline WL corresponding to the row address RA. For example, the activated bank row decoder may generate a wordline driving voltage, and may apply the wordline driving voltage to the wordline WL corresponding to the row address RA.

The column address latch 250 may receive the column address COL_ADDR from the address register 220, and may temporarily store the received column address COL_ADDR. In some example embodiments, in a burst mode, the column address latch 250 may generate column addresses that increment from the received column address COL_ADDR. The column address latch 250 may apply the temporarily stored or generated column address to the first to eighth bank column decoders 270a to 270h.

The activated one of the first to eighth bank column decoders 270a to 270h may decode the column address COL_ADDR that is output from the column address latch 250, and may control the I/O gating circuit 290 to output data corresponding to the column address COL_ADDR.

The I/O gating circuit 290 may include circuitry for gating input/output data. The I/O gating circuit 290 may further include read data latches for storing data that is output from the first to eighth bank arrays 310 to 380, and may also include write control devices for writing data to the first to eighth bank arrays 310 to 380.

A codeword CW read from one of the first to eighth bank arrays 310 to 380 may be sensed by a sense amplifier connected to the one bank array from which the codeword CW is to be read, and may be stored in the read data latches. The codeword CW stored in the read data latches may be provided to the memory controller 100 via the data I/O buffer 295 after the on-die ECC engine 400a performs an ECC decoding on the codeword CW. The codeword CW may be provided to the memory controller 100 as data set (or user data or main data) DQ_BL.

The data set DQ_BL to be written in one of the first to eighth bank arrays 310 to 380 may be provided to the data I/O buffer 295 from the memory controller 100, and may be provided to the on-die ECC engine 400a from the data I/O buffer 295. The on-die ECC engine 400a may perform an ECC encoding on the data set DQ_BL to generate parity data, the on-die ECC engine 400a may provide the codeword CW including the data set DQ_BL and the parity data to the I/O gating circuit 290, and the I/O gating circuit 290 may write the codeword CW in a sub-page of a target page in one bank array through the write drivers.

The data I/O buffer 295 may provide the data set DQ_BL from the memory controller 100 to the on-die ECC engine 400a in a write operation of the data chip 201a, and may provide the data set DQ_BL from the on-die ECC engine 400a to the memory controller 100 in a read operation of the data chip 201a.

The control logic circuit 212 may control operations of the data chip 201a. For example, the control logic circuit 212 may generate control signals for the data chip 201a to perform the write operation and/or the read operation. The control logic circuit 212 may include a command decoder 213 that decodes the command CMD received from the memory controller 100, and a mode register 214 that sets an operation mode of the data chip 201a. In some example embodiments, operations described herein as being performed by the control logic circuit 212 may be performed by processing circuitry. The command decoder 213 may generate the control signals corresponding to the command CMD by decoding a write enable signal, a row address strobe signal, a column address strobe signal, a chip select signal, etc.

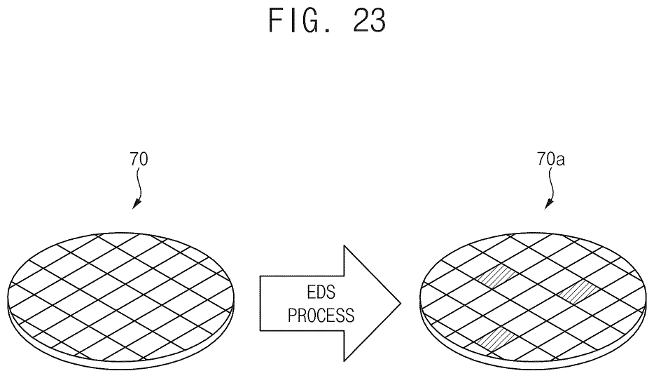

FIG. 23 is a diagram for describing a configuration and an operation of a clock signal driver according to example embodiments. Referring to FIG. 23, an example of an electrical die sorting (EDS) process that is performed while a nonvolatile memory device is manufacturing is illustrated. After a plurality of nonvolatile memory chips are fabricated by performing an oxidation process, a photolithography process, an etching process, a deposition and/or ion implantation process, a metal wiring process, etc. on a wafer, the EDS process may be performed to check whether each nonvolatile memory chip has reached a target quality level. For example, electrical tests, wafer burn-in tests, hot/cold tests, repair/final tests, etc. may be performed, and finally, defective chips may be identified by inking. For example, the EDS process may be used with substantially the same meaning as the wafer test process. For example, the correction operation described with reference to FIGS. 6 to 9 may be performed in the EDS process. The correction operation may represent the operation of correcting the delay change in the output clock signal that occurs according to the change in the voltage level of the power supply voltage. For example, the EDS process may include a trimming code generation operation to correct the delay change in the output clock signal according to a plurality of test voltage levels of the power supply voltage.

For example, a wafer 70 on the left side in FIG. 23 may represent a wafer before the EDS process, a wafer 70a on the right side in FIG. 23 may represent a wafer after the EDS process, and hatched portions in the wafer 70a may represent defective chips.

In some example embodiments, the EDS test operation may be performed while the nonvolatile memory device is manufacturing, and the EDS test operation may not be performed again thereafter. For example, each nonvolatile memory chip (e.g., the nonvolatile memory chip 50 in FIG. 5) may be provided by cutting the wafer 70a after the EDS process, and thus it may be impossible to perform the EDS process and/or the EDS test operation thereafter.

The example embodiments may be applied to various electronic devices and systems that include the clock signal driver. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments.

Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A clock signal driver, comprising:
a driver circuit configured generate an output clock signal in response to an input clock signal, a delay control signal and a power supply voltage, said driver circuit comprising:
a main driver circuit configured to generate the output clock signal in response to the input clock signal; and
a replica circuit having a structure equivalent to the main driver circuit, said replica circuit configured to generate a replica clock signal, which is equivalent to the output clock signal, in response to the input clock signal; and
a delay control circuit responsive to the replica clock signal, said delay control circuit configured to generate the delay control signal to correct a delay change in the output clock signal, which is caused by a change in voltage level of the power supply voltage.

2. The clock signal driver of claim 1, wherein the delay control circuit is powered by a first voltage, which is different from the power supply voltage and has a constant voltage level.

3. The clock signal driver of claim 1, wherein the delay control signal is generated by delay control circuit and in response to the replica clock signal, during a wafer level test of the clock signal driver.

4. The clock signal driver of claim 1, wherein the delay control circuit includes:
a flip-flop configured to output a result signal in response to the replica clock signal and a unit pulse signal; and
a logic calculating circuit configured to generate: (i) the unit pulse signal as feedback to the flip-flop, and (ii) the delay control signal based on the result signal.

5. The clock signal driver of claim 4,
wherein the logic calculating circuit is configured to store a plurality of first time points that occur while changing the voltage level of the power supply voltage, and to generate the delay control signal based on the plurality of first time points; and
wherein the plurality of first time points indicate time points when the result signal transitions between logic levels.

6. The clock signal driver of claim 4, wherein the unit pulse signal has an activation time interval corresponding to 1 unit interval (UI) of data that is input to and output from a memory device operating based on the output clock signal.

7. The clock signal driver of claim 1, wherein the driver circuit further includes:
a control circuit configured to receive the input clock signal, and to generate a first clock signal by adjusting a phase or a delay of the input clock signal; and
a main driver operating circuit configured to generate a second clock signal in response to the first clock signal and the delay control signal; and
wherein the main driver circuit is configured to generate the output clock signal based on the second clock signal, and the replica circuit is configured to generate the replica clock signal based on the second clock signal.

8. The clock signal driver of claim 7, wherein the delay control signal includes a trimming code applied to the main driver operating circuit to correct the delay change in the output clock signal.

9. The clock signal driver of claim 8,
wherein the delay control signal further includes a register signal for changing a device setting value of the driver circuit to additionally correct the delay change in the output clock signal; and
wherein the device setting value includes a gain of the control circuit, an intensity of a current flowing through the control circuit and a transistor strength of the main driver circuit.

10. The clock signal driver of claim 7, wherein the main driver operating circuit includes:
a pre-driver circuit configured to amplify the first clock signal; and
a delay cell circuit configured to correct the delay change in the output clock signal that occurs in response to changes in the voltage level of the power supply voltage.

11. The clock signal driver of claim 10,
wherein the pre-driver circuit includes a plurality of inverters connected in series; and
wherein the delay cell circuit includes a plurality of variable resistors and a plurality of variable capacitors that are connected to the plurality of inverters.

12. The clock signal driver of claim 11,
wherein the plurality of inverters include a first inverter and a second inverter, and an input of the first inverter and an output of the second inverter are connected to a first node;
wherein the plurality of variable resistors include a first variable resistor, and the plurality of variable capacitors include a first variable capacitor; and
wherein the first variable resistor and the first variable capacitor are connected in series between the first node and a ground voltage.

13. The clock signal driver of claim 10, wherein the delay cell circuit is configured to apply a delay that increases as the voltage level of the power supply voltage increases to the first clock signal.

14. The clock signal driver of claim 10, wherein the delay cell circuit is configured to apply a delay that increases linearly in proportion to the voltage level of the power voltage to the first clock signal.

15. The clock signal driver of claim 7, wherein the control circuit includes:
a receiving circuit configured to receive and amplify the input clock signal;
a clock tree circuit configured to correct a delay difference depending on a transmission path of the input clock signal; and
a phase locked loop configured to lock a phase of the input clock signal.

16. The clock signal driver of claim 15, wherein the receiving circuit includes a plurality of buffers configured to amplify the input clock signal.

17. The clock signal driver of claim 15, wherein the first clock signal is generated based on one of the clock tree circuit and the phase locked loop.

18. A memory system, comprising:
a clock signal driver configured to generate an output clock signal in response to an input clock signal, said clock signal driver comprising:
a driver circuit configured to operate based on a power supply voltage, and to generate the output clock signal based on the input clock signal and a delay control signal, the driver circuit comprising:
a main driver circuit configured to generate the output clock signal; and
a replica circuit having a same structure as the main driver circuit, and configured to generate a replica clock signal identical to the output clock signal; and
a delay control circuit configured to generate the delay control signal for correcting a delay change in the output clock signal based on the replica clock signal, the delay change in the output clock signal occurring depending on a change in a voltage level of the power supply voltage;
a plurality of memory devices configured to receive the output clock signal from the clock signal driver; and
a host device configured to supply the input clock signal to the clock signal driver, and to control the clock signal driver and the plurality of memory devices.

19. The memory system of claim 18, wherein each of the plurality of memory devices is a dynamic random access memory (DRAM) device.

20. A clock signal driver, comprising:
a driver circuit configured to operate based on a power supply voltage, and to generate an output clock signal in response to an input clock signal and a delay control signal, the driver circuit comprising:
a control circuit configured to receive the input clock signal, and to generate a first clock signal by adjusting a phase or a delay of the input clock signal;
a main driver operating circuit configured to generate a second clock signal in response to the first clock signal and the delay control signal;
a main driver circuit configured to generate the output clock signal in response to the second clock signal; and
a replica circuit having a same structure as the main driver circuit, and configured to generate a replica clock signal identical to the output clock signal; and
a delay control circuit configured to operate based on a first voltage that is different from the power supply voltage and has a constant voltage level, the delay control circuit comprising:
a flip-flop configured to output a result signal in response to the replica clock signal and a unit pulse signal; and
a logic calculating circuit configured to generate the unit pulse signal, and to generate the delay control signal for correcting a delay change in the output clock signal in response to the result signal, with the delay change in the output clock signal occurring in response to a change in a voltage level of the power supply voltage.
